(19) United States
(12) Patent Application Publication
(10) Pub. No.: US 2024/0412943 A1
(43) Pub. Date: Dec. 12, 2024

(54) SUBSTRATE INSPECTION METHOD

(71) Applicant: Samsung Electronics Co., Ltd., Suwon-si, Gyeonggi-do (KR)

(72) Inventors: Jinwoo Lee, Suwon-si, Gyeonggi-do (KR); Bumjoo Lee, Suwon-si, Gyeonggi-do (KR); Jong Cheon Sun, Suwon-si, Gyeonggi-do (KR); Suyoung Lee, Suwon-si, Gyeonggi-do (KR); Hyeongcheol Lee, Suwon-si, Gyeonggi-do (KR)

(21) Appl. No.: 18/528,851

(22) Filed: Dec. 5, 2023

(30) Foreign Application Priority Data
Jun. 6, 2023 (KR) 10-2023-0077380

(51) Int. Cl. H01J 37/26; H01J 37/28

(52) U.S. Cl. CPC H01J 37/265; H01J 37/28; H01J 2237/2594; H01J 2237/2817

(57) ABSTRACT

A substrate inspection method includes reducing a surface potential of a substrate; and increasing a difference of the surface potential of the substrate, where reducing the surface potential of the substrate includes: controlling a scanning electron microscope to irradiate an electron beam to the substrate for a first irradiation time; and after a first standby time has elapsed, controlling the scanning electron microscope to re-irradiate the electron beam to the substrate for the first irradiation time, where increasing the difference of the surface potential of the substrate includes: controlling the scanning electron microscope to irradiate the electron beam to the substrate for a second irradiation time; and after a second standby time has elapsed, controlling the scanning electron microscope to re-irradiate the electron beam to the substrate for the second irradiation time, and where the first irradiation time is less than the second irradiation time.

### CROSS-REFERENCE TO RELATED APPLICATION

This U.S. nonprovisional application claims priority under 35 U.S.C. § 119 to Korean Patent Application No. 10-2023-0077380 filed on Jun. 16, 2023 in the Korean Intellectual Property Office, the disclosure of which is hereby incorporated by reference in its entirety.

### TECHNICAL FIELD

The present disclosure relates to a substrate inspection method, and more particularly, to a substrate inspection method in which a domain having an electrically insulated structure on a substrate is inspected by using a difference in capacitance with a variation in gray level.

### BACKGROUND

An electronic microscope may include a transmission electron microscope (TEM) and a scanning electron microscope (SEM).

The transmission electron microscope may be configured such that an electron beam with high energy is transmitted through an electronic lens and a sample to form an image on a fluorescent screen. The transmission electron microscope may obtain an image formed by contrast due to differences in sample density, thickness, and so forth, and may diffract the electron beam to acquire information about an inside of an element.

The scanning electron microscope uses secondary electrons or backscattered electrons that have a higher probability of occurrence among various signals generated from a sample when an electron beam scans over the surface of the sample. The scanning electron scope may obtain information about the surface of the sample and have an advantage of a lack of limitations regarding a size and preparation of the sample.

### SUMMARY

Some embodiments of the present disclosure provide a substrate inspection method configured to increase an overall gray level of a sample.

Some embodiments of the present disclosure provide a substrate inspection method configured to increase a difference in gray level between targets having different capacitances.

Some embodiments of the present disclosure provide a substrate inspection method configured to reduce an overall surface potential of a sample.

Some embodiments of the present disclosure provide a substrate inspection method configured to increase a difference in overall surface potential between targets having different capacitances.

Some embodiments of the present disclosure provide a substrate inspection method configured to inspect defects of electrically insulated structures.

The object of the present disclosure is not limited to the mentioned above, and other objects which have not been mentioned above will be clearly understood to those skilled in the art from the following description.

According to some embodiments of the present disclosure, a substrate inspection method may comprise: executing, by a controller coupled to a scanning electron microscope, instructions stored in a non-transitory storage medium to perform operations including: reducing a surface potential of a substrate; and increasing a difference of the surface potential of the substrate, where reducing the surface potential of the substrate includes: controlling the scanning electron microscope to irradiate an electron beam to the substrate for a first irradiation time; and in response to controlling the scanning electron microscope to irradiate the electron beam to the substrate for the first irradiation time and after a first standby time has elapsed, controlling the scanning electron microscope to re-irradiate the electron beam to the substrate for the first irradiation time, where increasing the difference of the surface potential of the substrate includes: controlling the scanning electron microscope to irradiate the electron beam to the substrate for a second irradiation time; and in response to controlling the scanning electron microscope to irradiate the electron beam to the substrate for the second irradiation time and after a second standby time has elapsed, controlling the scanning electron microscope to re-irradiate the electron beam to the substrate for the second irradiation time, and where the first irradiation time is less than the second irradiation time.

According to some embodiments of the present disclosure, a substrate inspection method may comprise: executing, by a controller coupled to a scanning electron microscope, instructions stored in a non-transitory storage medium to perform operations including: reducing a surface potential of a substrate; increasing a difference of the surface potential of the substrate; and observing the substrate by irradiating an electron beam to the substrate, where the substrate includes a first domain and a second domain, where reducing the surface potential of the substrate includes: irradiating the electron beam to the first domain and the second domain for a first irradiation time; and in response to controlling the scanning electron microscope to irradiate the electron beam to the first domain and the second domain for the first irradiation time and after a first standby time, re-irradiating the electron beam to the first domain and the second domain for the first irradiation time, where increasing the difference of the surface potential includes: irradiating the electron beam to the first domain and the second domain for a second irradiation time; and in response to controlling the scanning electron microscope to irradiate the electron beam to the first domain and the second domain for the second irradiation time and after a second standby time, re-irradiating the electron beam to the first domain and the second domain for the second irradiation time, and where observing the substrate includes measuring, by a scanning electron microscope, a difference between a gray level of the first domain and a gray level of the second domain.

According to some embodiments of the present disclosure, a substrate inspection method may comprise: executing, by a controller coupled to a scanning electron microscope, instructions stored in a non-transitory storage medium to perform operations including: increasing a gray level of a substrate; and increasing a difference of the gray level of the substrate, where the substrate includes a first domain and a second domain, where increasing the gray level of the substrate includes controlling the scanning electron microscope to irradiate an electron beam to the substrate for a first irradiation time to increase a gray level of each of the first domain and the second domain, where increasing the difference in gray level of the substrate includes controlling the scanning electron microscope to irradiate the electron beam to the substrate for a second irradiation time, and where the second irradiation time is greater than the first irradiation time.

Details of other example embodiments are included in the description and drawings.

### BRIEF DESCRIPTION OF DRAWINGS

FIG. 1 illustrates a simplified schematic diagram showing a scanning electron microscope according to some embodiments of the present disclosure.

FIG. 2 illustrates an enlarged view showing a scanning electron microscope according to some embodiments of the present disclosure.

FIG. 3 illustrates a flow chart showing a substrate inspection method according to some embodiments of the present disclosure.

FIG. 4 illustrates a graph showing a variation in gray level that occurs during the execution of image observation including a substrate inspection method according to the flow chart of FIG. 3.

FIG. 5 illustrates a simplified view showing before and after diagrams of electron beam irradiation to a substrate according to some embodiments of the present disclosure.

FIGS. 6, 7, 8, 9, 10, and 11 illustrate substrate images observed when a substrate inspection method is performed according to the flow chart of FIG. 3.

FIG. 12 illustrates a flow chart showing a substrate inspection method according to some embodiments of the present disclosure.

### DETAILED DESCRIPTION OF EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

The present disclosure has been described herein with reference to flowchart and/or block diagram illustrations of methods, systems, and devices in accordance with exemplary embodiments of the invention. It will be understood that each block of the flowchart and/or block diagram illustrations, and combinations of blocks in the flowchart and/or block diagram illustrations, may be implemented by computer program instructions and/or hardware operations. These computer program instructions may be provided to a processor of a general purpose computer, a special purpose computer, or other programmable data processing apparatus to produce a machine, such that the instructions, which execute via the processor of the computer or other programmable data processing apparatus, create means for implementing the functions specified in the flowchart and/or block diagram block or blocks.

These computer program instructions may also be stored in a non-transitory computer usable or computer-readable memory that may direct a computer or other programmable data processing apparatus to function in a particular manner, such that the instructions stored in the computer usable or computer-readable memory produce an article of manufacture including instructions that implement the function specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart and/or block diagram block or blocks.

The following will now describe some embodiments of the present disclosure with reference to the accompanying drawings. Like reference numerals may indicate like components throughout the description.

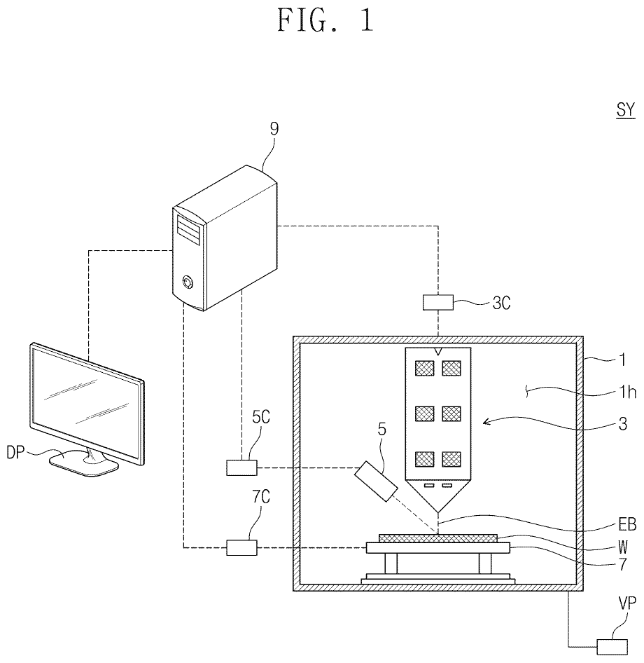

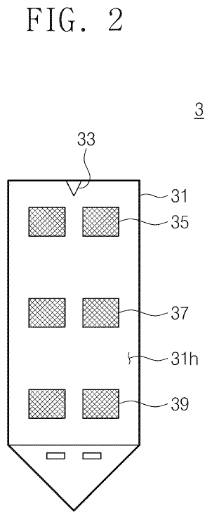

FIG. 1 illustrates a simplified schematic diagram showing a scanning electron microscope SY according to some embodiments of the present disclosure. FIG. 2 illustrates an enlarged view showing the scanning electron microscope SY according to some embodiments of the present disclosure.

Referring to FIG. 1, the scanning electron microscope (SEM) SY may be provided. The scanning electron microscope SY may include a chamber 1, a column 3, a test stage 7, a detector 5, a test stage driving mechanism 7C, a column controller 3C, a detector controller 5C, an integrated controller 9, a vacuum pump VP, and a display DP.

The chamber 1 may provide an inspection space 1h. The inspection space 1h may be kept in a vacuum state. The vacuum pump VP may control the inspection space 1h such that it remains in the vacuum state. For example, an inside of the chamber 1 may be kept in the vacuum state by the vacuum pump VP. A substrate W may be disposed in the chamber 1. For example, the substrate W may be placed on the test stage 7 in the chamber 1. The term “substrate” used in this disclosure may denote a semiconductor device. For example, the substrate W may include a silicon (Si) wafer. The present disclosure, however, is not limited thereto, and the substrate W may correspond to a semiconductor device that is shaped like a divided individual die.

At least a portion of the column 3 may be positioned in the chamber 1. The column 3 may irradiate an electron beam EB toward the substrate W on test stage 7. The column 3 may irradiate the electron beam EB to the substrate W to electrically charge a conductor, such as an electrode of the substrate W. For example, the column 3 may irradiate a charging electron beam. For example, when the electron beam EB whose secondary electron yield is greater than about 1 is irradiated to the substrate W, an electrode of the substrate W may be charged with positive charges. As another example, when the electron beam EB whose secondary electron yield is less than about 1 is irradiated to the substrate W, an electrode of the substrate W may be charged with negative charges. The column 3 may irradiate a scanning electron beam toward the substrate W on the test stage 7. The scanning electron beam may scan an electrode of the substrate W charged with a charging electron beam.

It is illustrated and described that one column 3 is provided, but the present disclosure is not limited thereto. For example, two columns 3 may be provided. In this case, one of the two columns 3 may irradiate a charging electron beam, and the other of the two columns 3 may irradiate a scanning electron beam.

The test stage 7 may be positioned below the column 3. The test stage 7 may support the substrate W. The substrate W may be disposed on a top surface of the test stage 7. The test stage 7 may include a chuck for holding the substrate W. For example, the test stage 7 may include an electrostatic chuck (ESC) that uses an electrostatic voltage to hold the substrate W or a vacuum chuck that uses a vacuum pressure to hold the substrate W. The test stage 7 may be movable in a horizontal direction with respect to the column 3. Therefore, the substrate W on the test stage 7 may also be movable in a horizontal direction with respect to the column 3.

The detector 5 may detect an emitted electron (referred to hereinafter as a secondary electron) and/or a backscattered electron that is emitted from the substrate W by the electron beam EB. For example, the detector 5 may detect a secondary electron that escapes from the substrate W to which the electron beam EB is irradiated. The integrated controller 9 may receive information about the secondary electron detected by the detector 5.

The test stage driving mechanism 7C may move the test stage 7. For example, the test stage driving mechanism 7C may move the test stage 7, on which the substrate W is disposed, in a horizontal direction.

The column controller 3C may control the column 3. For example, the column controller 3C may control an irradiation time, a secondary electron yield, and an angle of the electron beam EB irradiated from the column 3. In addition, the column controller 3C may control a path of the electron beam EB irradiated from the column 3.

The detector controller 5C may control the detector 5. The detector controller 5C may provide the integrated controller 9 with information detected from the detector 5. The integrated controller 9 may control the column controller 3C, the detector controller 5C, and the test stage driving mechanism 7C. The integrated controller 9 may generate an image by using information about secondary electrons received from the detector 5. For example, the integrated controller 9 may generate a voltage contrast (VC) image. Alternatively, the integrated controller 9 may yield numerical data about an amount of secondary electrons by using information about secondary electrons received from the detector 5. For example, the integrated controller 9 may yield numerical data about electrical signals caused by secondary electrons received from the detector 5 and may obtain scanning electron microscope (SEM) images. The SEM image may be a two-dimensional image. The integrated controller 9 may obtain SEM images with different gray levels. The gray level may express a numerical value exhibiting brightness of each pixel. For example, a 256 gray level SEM image may have a contrast range of about 0 to about 255. An increase in gray level of a SEM image may cause an increase in brightness. The display DP may be connected to the integrated controller 9. The display DP may output an image built by the integrated controller 9. The image released from the display DP may be observed to determine whether the substrate W is defective or not. A detailed description thereof will be further discussed below.

Referring to FIG. 2, the column 3 may include a housing 31, an electron gun 33, a condenser lens 35, a deflector 37, and an objective lens 39.

The housing 31 may provide a beam generation space 31h. The housing 31 may protect or encapsulate the electron gun 33.

The electron gun 33 may be positioned in the beam generation space 31h. The electron gun 33 may irradiate the electron beam EB onto the substrate W. The electron gun 33 may produce and accelerate electrons. The electron gun 33 may include a filament formed of metal, such as tungsten. When the electron gun 33 heats the filament to a high temperature, electrons bound to an atom may be emitted to the vacuum. The electron beam EB emitted from the electron gun 33 may pass through the deflector 37 to move outside the housing 31. The electron gun 33 may include an anode (not shown). The anode may use a high voltage to acceleration electrons released from the filament.

The condenser lens 35 may be positioned below the electron gun 33. The condenser lens 35 may condense the electron beam EB onto a narrow section. The condenser lens 35 may have a cylindrical shape, but the present disclosure is not limited thereto. The condenser lens 35 may include an electromagnet and/or a condenser. The condenser lens 35 may adjust a propagation direction of the electron beam EB by using a Lorentz force applied to the electron beam EB that moves in a magnetic field.

The deflector 37 may be positioned below the electron gun 33. For example, the deflector 37 may be placed below the condenser lens 35. The deflector 37 may deflect the path of the electron beam EB. For example, the deflector 37 may bend the path of the electron beam EB emitted from the electron gun 33. For example, the electron beam EB emitted from the electron gun 33 may downwardly travel straight (i.e., in a vertical direction), and then the path of the electron beam EB may be bent while passing through the deflector 37. Therefore, the deflector 37 may direct the electron beam EB to an intended location. A single deflector 37 is provided in this disclosure, but a plurality of deflectors 37 may be provided. The plurality of deflectors 37 may bend the moving path of the electron beam EB in different directions. The deflector 37 may include an electromagnet and/or a condenser. The present disclosure, however, is not limited thereto, and the deflector 37 may include any other suitable structures that are configured to change the path of the electron beam EB.

The objective lens 39 may be positioned below the electron gun 33. For example, the objective lens 39 may be placed below the deflector 37. The objective lens 39 may be disposed adjacent to a top surface of the substrate W. The objective lens 39 may allow the electron beam EB passing through the deflector 37 to collect on the substrate W. For example, the objective lens 39 may focus the electron beam EB onto the substrate W. The objective lens 39 may include two scanning coils (not shown) and a pair of stigmators (not shown). The scanning coil may systematically move a focus of the electron beam EB formed on a surface of the substrate W. The stigmators may correct a non-circular focus of a secondary electron emitted from the substrate W.

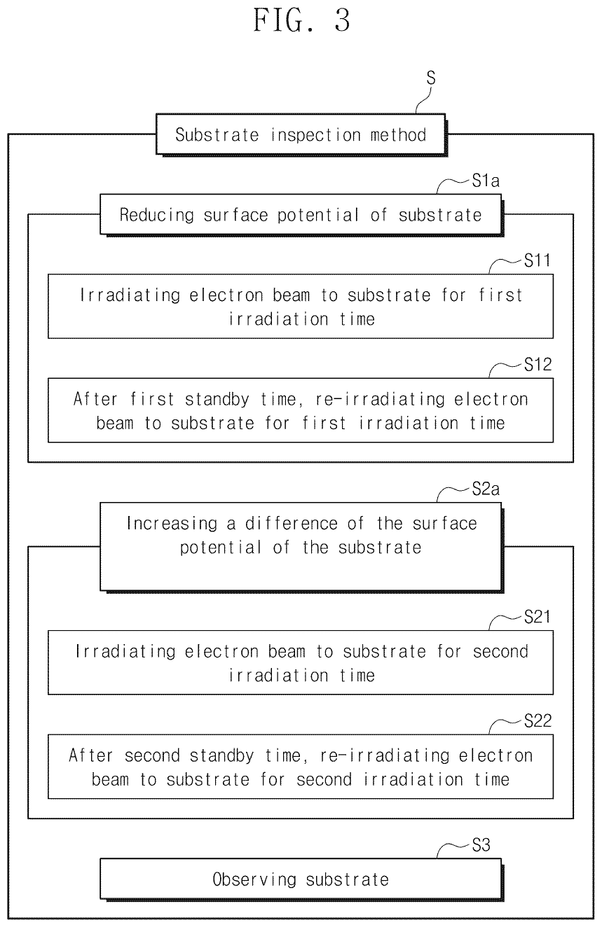

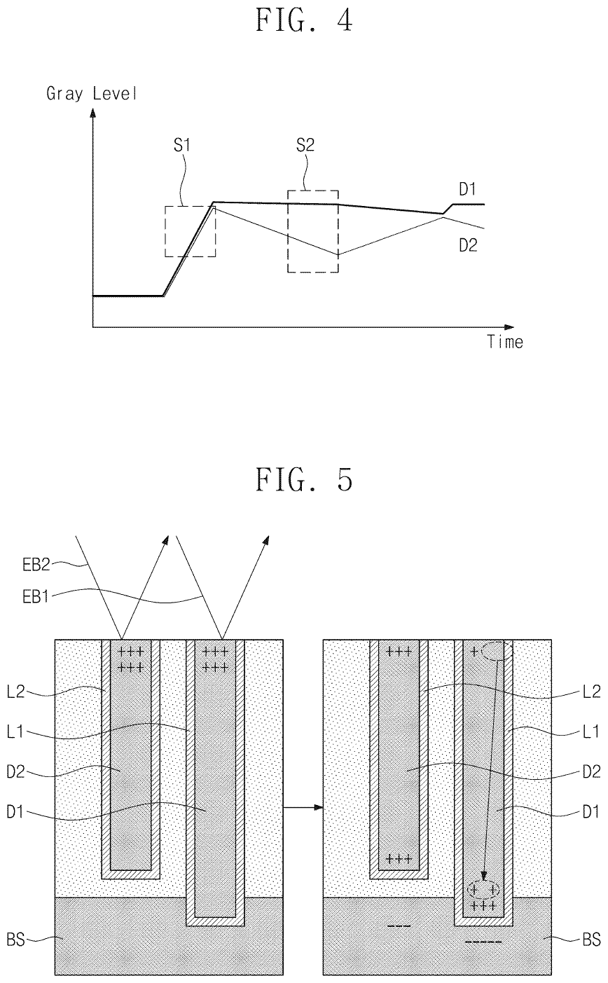

FIG. 3 illustrates a flow chart of a substrate inspection method S according to some embodiments of the present disclosure. FIG. 4 illustrates a graph showing a variation in gray level that occurs during the execution of image observation including the substrate inspection method S according to the flow chart of FIG. 3. FIG. 5 illustrates a simplified view showing before and after irradiation of the electron beam EB to the substrate W according to some embodiments of the present disclosure.

Referring to FIG. 3, the substrate inspection method S may include reducing a surface potential of the substrate W (S1a), increasing a difference in surface potential of the substrate W (S2a), and observing the substrate W (S3). The reducing of the surface potential of the substrate W (S1a) may include, after a first standby time, irradiating the electron beam EB to the substrate W for a first irradiation time (S11) and re-irradiating the electron beam EB to the substrate W for the first irradiation time (S12). The increasing of the difference in surface potential of the substrate W (S2a) may include, after a second standby time, irradiating the electron beam EB to the substrate W for a second irradiation time (S21) and re-irradiating the electron beam EB to the substrate W for the second irradiation time (S22).

In this disclosure, the reduction step S1a may be referred to as a first step S1. The increase step S2a may be referred to as a second step S2. The substrate W may include a first domain D1 and a second domain D2. The first domain D1 and the second domain D2 may have different capacitances.

Referring to FIG. 4, a horizontal axis may refer to a time. A vertical axis may refer to a gray level. In FIG. 4, symbol D1 is associated with a graph showing a gray level at the first domain D1. In FIG. 4, symbol D2 is associated with a graph showing a gray level at the second domain D2. At the first step S1, the scanning electron microscope SY may be used to reduce a surface potential of the substrate W. When the substrate W has a reduced surface potential, a SEM image may have an increased gray level. For example, when the substrate W has a reduced overall surface potential, the first domain D1 and the second domain D2 may have SEM images with increased gray levels. The first step S1 may include irradiating the electron beam EB to the substrate W for a first irradiation time (S11), and after a first standby time, re-irradiating the electron beam EB to the substrate W for the first irradiation time (S12). For example, the first step S1 may include irradiating the electron beam EB to the first domain D1 and the second domain D2 for a first irradiation time (S11), and after a first standby time, re-irradiating the electron beam EB to the first domain D1 and the second domain D2 for the first irradiation time (S12). The first standby time may be greater than or equal to about 10,000 times the first irradiation time. The first irradiation time may be a relatively short time. For example, the first irradiation time may be less than or equal to about 100 ms. The present disclosure, however, is not limited thereto, and the first irradiation time and the first standby time may vary based on a structure of the substrate W.

Referring to FIG. 4, at the second step S2, the scanning electron microscope SY may be used to increase a surface potential of the substrate W. When the substrate W has an increased surface potential, a SEM image may have an increased gray level. For example, when the substrate W has an increased surface potential, the first domain D1 and the second domain D2 may have their SEM images whose difference in gray level is increased. In this disclosure, the first domain D1 may have capacitance greater than that of the second domain D2. As the second step S2 is performed, the gray level of the second domain D2 may be lower than that of the first domain D1. The second step S2 may include irradiating the electron beam EB to the substrate W for a second irradiation time (S21), and after a second standby time, re-irradiating the electron beam EB to the substrate W for the second irradiation time (S22). For example, the second step S2 may include irradiating the electron beam EB to the first domain D1 and the second domain D2 for a second irradiation time (S21), and after a second standby time, re-irradiating the electron beam EB to the first domain D1 and the second domain D2 for the second irradiation time (S22). The irradiation of the electron beam EB to the substrate W for the second irradiation time may create a difference in surface potential between domains D1 and D2 of the substrate W. For example, when the electron beam EB is irradiated to the substrate W for the second irradiation time, a difference in surface potential may be created due to a difference in capacitance between the first domain D1 and the second domain D2. The irradiation of the electron beam EB to the substrate W for the second irradiation time may include creating a difference in surface potential due to a difference in capacitance between the first domain D1 and the second domain D2. The second standby time may be greater than or equal to about 10,000 times the second irradiation time. The second irradiation time may be greater than the first irradiation time. For example, the first irradiation time may be less than the second irradiation time.

Referring to FIG. 5, when the electron beam EB is irradiated to the substrate W, a surface potential may be changed due to a difference in capacitance. The electron beam EB irradiated to the first domain D1 may be referred to as a first electron beam EB1. The electron beam EB irradiated to the second domain D2 may be referred to as a second electron beam EB2. The first electron beam EB1 and the second electron beam EB2 may have the same intensity, irradiation time, and standby time. The first domain D1 and the second domain D2 may be respectively surrounded by a first dielectric layer L1 and a second dielectric layer L2. The first dielectric layer L1 and the second dielectric layer L2 may include an oxide film and/or a nitride film. For example, the first dielectric layer L1 and the second dielectric layer L2 may include a silicon oxide (SiO₂) film, a silicon nitride (Si₃N₄) film, and/or a silicon oxynitride (SiON) film. A contact area between the first domain D1 and a base BS may be greater than that between the second domain D2 and the base BS. Therefore, the capacitance of the first domain D1 may be greater than that of the second domain D2. The relationship between the first domain D1 and the second domain D2 is not limited to that mentioned above. As the capacitance of the first domain D1 is greater than that of the second domain D2, after the electron beam EB is irradiated to the substrate W, a surface potential of the first domain D1 may be less than that of the second domain D2. For example, positive charges present on a surface of the first domain D1 may move toward the base BS. A reduction in surface potential of the substrate W may induce an increase in the number of secondary electrons emitted when the electron beam EB is irradiated, which may result in an increased gray level.

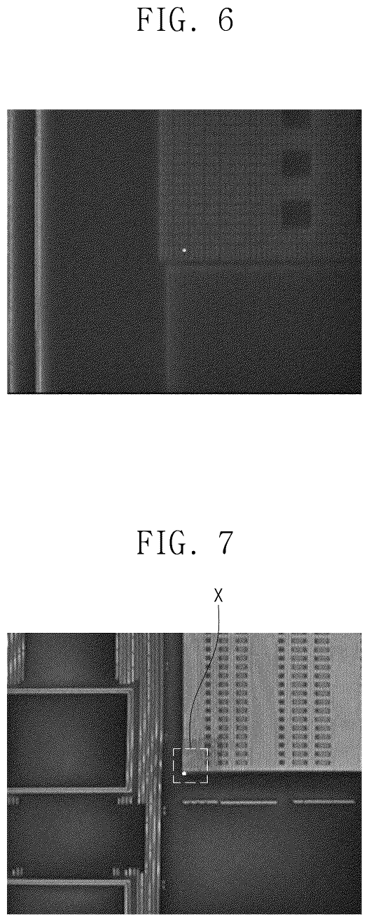

FIGS. 6 to 11 illustrate substrate images observed when the substrate inspection method S is performed according to the flow chart of FIG. 3.

Referring to FIG. 6, a SEM image observed before the first step S1 and the second step S2 in which the electron beam EB is irradiated to the substrate W is shown. The SEM image, which is observed before the first step S1 and the second step S2 are performed, may be dark. The SEM image observed before the first step S1 and the second step S2 are performed may not show a clear contrast between light and shade and thus it may be difficult to determine a structure of the substrate W.

Referring to FIG. 7, there may be provided a SEM image observed after the first step S1 is performed. The electron beam EB may be irradiated to the substrate W during the first irradiation time, and after the first standby time, the electron beam EB may be irradiated again for the first irradiation time. The relationship between the first irradiation time and the first standby time may be substantially the same as that discussed above. The repetition of the first step S1 may reduce a surface potential of the substrate W. The reduction in surface potential of the substrate W may induce an increase in a gray level of the SEM image. The reduction in surface potential of the substrate W may cause an increase in sharpness of the SEM image.

Referring to FIG. 8, an enlarged image showing section X of a SEM image of FIG. 7 after the first step S1 is performed is shown. The SEM image after the first step S1 is performed may have an increased gray level. In FIG. 8, a section other than the second domain D2 may be referred to as the first domain D1. The first domain D1 and the second domain D2 may have different capacitances. For example, the first domain D1 may have a capacitance greater than that of the second domain D2. The first domain D1 and the second domain D2 may have their gray levels greater than those before the first step S1 is performed.

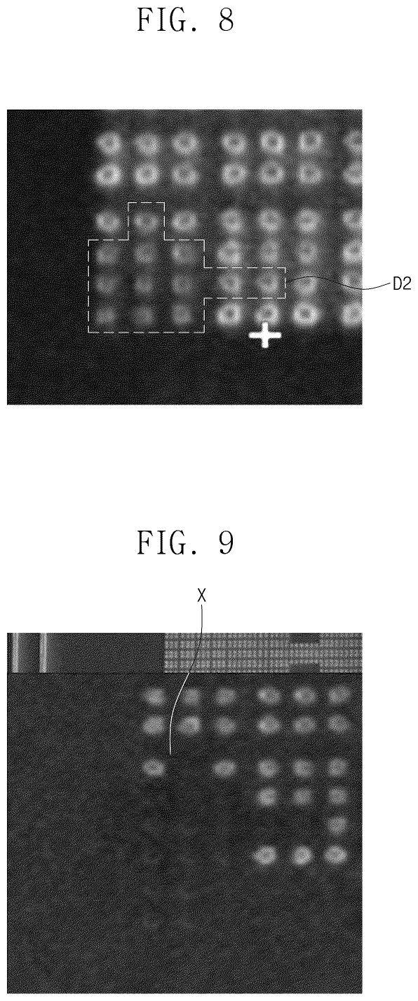

Referring to FIG. 9, a SEM image after the second step S2 is performed is shown. Referring to FIG. 10, there may be provided an enlarged image showing section X of a SEM image after the second step S2 is performed. The second step S2 may irradiate the electron beam EB to the substrate W for the second irradiation time. The second step S2 may repeatedly perform the procedure in which, after the second standby time, the electron beam EB is re-irradiated to the substrate W for the second irradiation time. Referring to FIG. 10, the second domain D2 may have a reduced gray level. A large difference in gray level may be provided between the first domain D1 and the second domain D2.

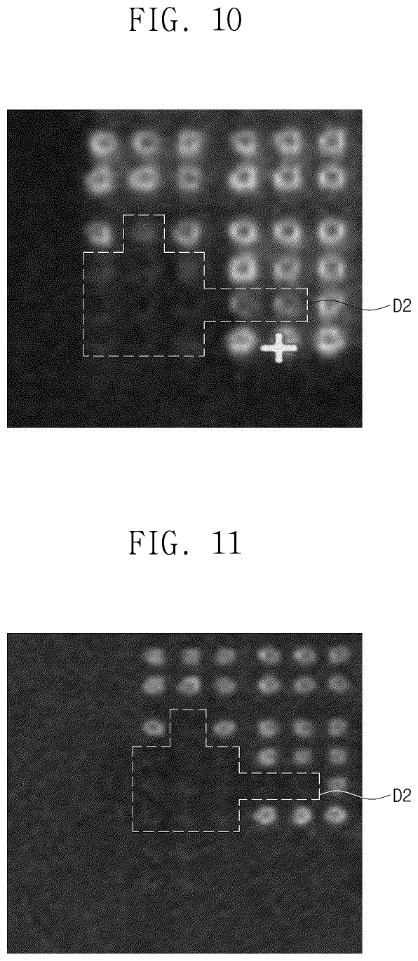

Referring to FIG. 11, a SEM image obtained when the substrate W is observed after the first step S1 and the second step S2 are performed is shown. The observation step S3 may include measuring a difference in gray level between the first domain D1 and the second domain D2. As a capacitance of the second domain D2 is less than that of the first domain D1, the second domain D2 may have a reduced gray level. As a surface potential of the second domain D2 is greater than that of the first domain D1, the second domain D2 may have a reduced gray level. Compared to the SEM image before the first step S1 and the second step S2 are performed, the first domain D1 and the second domain D2 may be clearly distinguished from each other.

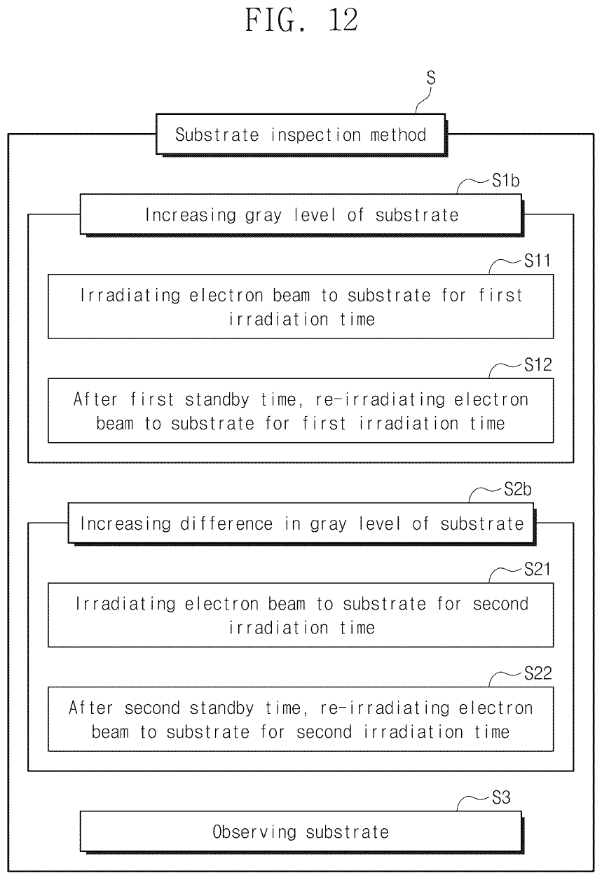

FIG. 12 illustrates a flow chart of a substrate inspection method S′ according to some embodiments of the present disclosure.

Referring to FIG. 12, the substrate inspection method S′ may include increasing a gray level of the substrate W (S1b), increasing a difference in gray level of the substrate W (S2b), and observing the substrate W (S3). The increasing of the gray level of the substrate W (S1b) may include controlling the scanning electron microscope SY to irradiate the electron beam EB to the substrate W for a first irradiation time to increase a gray level of each of the first domain D1 and the second domain D2. The increasing of the gray level of the substrate W (S1b) may include irradiating the electron beam EB to the substrate W for a first irradiation time (S11) and re-irradiating the electron beam EB to the substrate W for the first irradiation time after a first standby time (S12). The increasing of the difference in gray level of the substrate W (S2b) may include irradiating the electron beam EB to the substrate W for a second irradiation time (S21) and re-irradiating the electron beam EB to the substrate W for the second irradiation time after a second standby time (S22).

According to a substrate inspection method in accordance with some embodiments of the present disclosure, a substrate may have a reduced surface potential. Hence, there may be provided an increase in a gray level of a SEM image obtained by using a scanning electron microscope.

According to a substrate inspection method in accordance with some embodiments of the present disclosure, a difference in surface potential may increase due to a difference in a capacitance between domains of a substrate. Thus, there may be an increase in a difference in gray levels between domains in a SEM image.

According to a substrate inspection method in accordance with some embodiments of the present disclosure, domains having different capacitances may be distinguished and observed in accordance with a gray level. When each of a first domain and a second domain are normal, the first domain and the second domain may have the same structure and thus may have the same capacitance and gray level. When the capacitance of the second domain is changed due to the occurrence of a defect in the second domain, the gray level may be changed. The defective second domain may be observed as a difference in gray level in the SEM image.

According to a substrate inspection method of the present disclosure, a sample may have an increased overall gray level.

According to a substrate inspection method of the present disclosure, there may be an increase in difference in gray level between targets having different capacitances.

According to a substrate inspection method of the present disclosure, there may be a reduction in overall surface potential of a sample.

According to a substrate inspection method of the present disclosure, there may be an increase in difference in overall surface potential between targets having different capacitances.

According to a substrate inspection method of the present disclosure, defects may be inspected even in an electrically insulated structure.

Effects of the present disclosure are not limited to the mentioned above, other effects which have not been mentioned above will be clearly understood to those skilled in the art from the following description.

Although the present disclosure have been described in connection with some embodiments of the present disclosure illustrated in the accompanying drawings, it will be understood to those skilled in the art that various changes and modifications may be made without departing from the technical spirit and features of the present disclosure. It therefore will be understood that the embodiments described above are just illustrative but not limitative in all aspects.

What is claimed is:

1. A substrate inspection method, comprising:
executing, by a controller coupled to a scanning electron microscope, instructions stored in a non-transitory storage medium to perform operations comprising:
reducing a surface potential of a substrate; and
increasing a difference of the surface potential of the substrate,
wherein reducing the surface potential of the substrate comprises:
controlling the scanning electron microscope to irradiate an electron beam to the substrate for a first irradiation time; and
in response to controlling the scanning electron microscope to irradiate the electron beam to the substrate for the first irradiation time and after a first standby time has elapsed, controlling the scanning electron microscope to re-irradiate the electron beam to the substrate for the first irradiation time,
wherein increasing the difference of the surface potential of the substrate comprises:
controlling the scanning electron microscope to irradiate the electron beam to the substrate for a second irradiation time; and
in response to controlling the scanning electron microscope to irradiate the electron beam to the substrate for the second irradiation time and after a second standby time has elapsed, controlling the scanning electron microscope to re-irradiate the electron beam to the substrate for the second irradiation time, and
wherein the first irradiation time is less than the second irradiation time.

2. The method of claim 1, wherein the scanning electron microscope comprises:
a chamber;
an electron gun configured to generate and irradiate the electron beam to the substrate;
a deflector configured to deflect the electron beam;
an objective lens configured to focus the electron beam on the substrate; and
a detector configured to detect a secondary electron emitted from the substrate by the electron beam.

3. The substrate inspection method of claim 1, wherein the second standby time is greater than or equal to about 10,000 times the second irradiation time.

4. The substrate inspection method of claim 1, wherein the first standby time is greater than or equal to about 10,000 times the first irradiation time.

5. The substrate inspection method of claim 1, further comprising observing, by the scanning electron microscope, the substrate in response to controlling the scanning electron microscope to irradiate the electron beam to the substrate.

6. The substrate inspection method of claim 5, wherein the substrate comprises a first domain and a second domain, and wherein observing the substrate comprises measuring a difference between a gray level of the first domain and a gray level of the second domain.

7. The substrate inspection method of claim 2, wherein the scanning electron microscope further comprises a vacuum pump configured to maintain the chamber in a vacuum state.

8. The substrate inspection method of claim 1, wherein the substrate comprises a first domain and a second domain, and wherein the difference in surface potential is further based on a difference between a capacitance of the first domain and a capacitance of the second domain.

9. A substrate inspection method, comprising:
executing, by a controller coupled to a scanning electron microscope, instructions stored in a non-transitory storage medium to perform operations comprising:
reducing a surface potential of a substrate;
increasing a difference of the surface potential of the substrate; and
observing the substrate by irradiating an electron beam to the substrate,
wherein the substrate comprises a first domain and a second domain,
wherein reducing the surface potential of the substrate comprises:
irradiating the electron beam to the first domain and the second domain for a first irradiation time; and
in response to controlling the scanning electron microscope to irradiate the electron beam to the first domain and the second domain for the first irradiation time and after a first standby time, re-irradiating the electron beam to the first domain and the second domain for the first irradiation time,
wherein increasing the difference of the surface potential comprises:
irradiating the electron beam to the first domain and the second domain for a second irradiation time; and
in response to controlling the scanning electron microscope to irradiate the electron beam to the first domain and the second domain for the second irradiation time and after a second standby time, re-irradiating the electron beam to the first domain and the second domain for the second irradiation time, and
wherein observing the substrate comprises measuring, by the scanning electron microscope, a difference between a gray level of the first domain and a gray level of the second domain.

10. The method of claim 9, wherein:
the second irradiation time is greater than the first irradiation time, and
the first standby time is greater than or equal to about 10,000 times the first irradiation time.

11. The method of claim 9, wherein the second standby time is greater than or equal to about 10,000 times the second irradiation time.

12. The method of claim 9, wherein the difference of the surface potential is further based on a difference between a capacitance of the first domain and a capacitance of the second domain.

13. The method of claim 9, wherein a capacitance of the first domain is greater than a capacitance of the second domain, and wherein the gray level of the first domain is greater than the gray level of the second domain.

14. The method of claim 9, wherein the scanning electron microscope comprises:
a chamber;
an electron gun configured to irradiate electron beam to the substrate;
a deflector configured to deflect the electron beam;
an objective lens configured to focus the electron beam on the substrate; and
a detector configured to detect an electron emitted from the substrate by the electron beam.

15. The method of claim 14, wherein the scanning electron microscope further comprises a vacuum pump configured to maintain the chamber in a vacuum state, and wherein the controller generates numerical data associated with an amount of secondary electrons based on information associated with the secondary electrons detected by the detector.

16. A substrate inspection method, comprising:
executing, by a controller coupled to a scanning electron microscope, instructions stored in a non-transitory storage medium to perform operations comprising:
increasing a gray level of a substrate; and
increasing a difference of the gray level of the substrate,
wherein the substrate comprises a first domain and a second domain,
wherein increasing the gray level of the substrate comprises controlling the scanning electron microscope to irradiate an electron beam to the substrate for a first irradiation time to increase a gray level of each of the first domain and the second domain,
wherein increasing the difference in gray level of the substrate comprises controlling the scanning electron microscope to irradiate the electron beam to the substrate for a second irradiation time, and
wherein the second irradiation time is greater than the first irradiation time.

17. The method of claim 16, wherein the difference of the gray level of the substrate is based on a difference between a capacitance of the first domain and a capacitance of the second domain.

18. The method of claim 16, wherein increasing the difference in the gray level of the substrate comprises, in response to controlling the scanning electron microscope to irradiate the electron beam to the first domain and the second domain for the second irradiation time and after a second standby time, controlling the scanning electron microscope to irradiate the electron beam to the first domain and the second domain for the second irradiation time.

19. The method of claim 18, wherein the second standby time is greater than or equal to about 10,000 times the second irradiation time.

20. The method of claim 16, further comprising observing, by the scanning electron microscope, the substrate by detecting a secondary electron emitted from the substrate.
